(19) United States
(12) Patent Application Publication
(10) Pub. No.: US 2016/0125709 A1
(43) Pub. Date: May 5, 2016

(54) HAPTICS WRISTBAND

(71) Applicant: Novasentis, Inc., Burlingame, CA (US)

(72) Inventor: Brian Thaler, State College, PA (US)

(21) Appl. No.: 14/530,395

(22) Filed: Oct. 31, 2014

(51) Int. Cl. G08B 6/00; H01L 41/193; G10K 9/125; H01L 41/09

(52) U.S. Cl. CPC G08B 6/00; H01L 41/09; H01L 41/193; G10K 9/125

(57) ABSTRACT

EMP actuators are provided on a band intended for a wearable electronic device. Such a band may include (a) a flexible circuit having provided thereon an electrical interface to the wearable electronic device and conductive traces for distributing control signals received from the wearable electronic device over the electrical interface to predetermined locations on the flexible circuit; (b) electromechanical polymer (EMP) actuators each being mounted on one of the predetermined locations and each being connected by the conductive traces to receive one or more of the control signals; and (c) a protective covering over the flexible circuit and the EMP actuators.

### BACKGROUND OF THE INVENTION

1. Field of the Invention

The present invention relates to an application of electromechanical polymer (EMP) transducers. In particular, the present invention relates to a wristband for a wearable device, which is equipped with EMP actuators to provide haptic sensations.

2. Discussion of the Related Art

In the consumer electronic space, there is a need for providing haptic sensations (e.g., vibrations) to a wearer of a wearable electronic device. In such an application, a very thin wearable device is highly prized. Such a wearable device may be, for example, a “smart watch.” However, current haptic actuators, such as linear resonant actuators (LRAs) and eccentric rotating mass actuators (ERMs), are large and bulky. These LRAs and ERMs are typically provided on the functional display of the wearable device (e.g., the face plate), such that the wristband that is worn on a user's wrist serves merely to add weight to the system. Such a wristband would dampen the haptic sensations created by the vibrations of the actuators that are mounted on or embedded in the watch itself, as the weight of the wearable device is distributed circumferentially around the wrist of the wearer. In addition, such a watchband is not always worn very tightly against the body, so that the amount of body contact depends on the user's tightening of the band and the watchband's orientation. These factors further reduce the chance that haptic sensations by an actuator mounted on or embedded in the functional display of the wearable electronic device is perceptible to the user.

### SUMMARY

According to one embodiment of the present invention, a number of electromechanical polymer (EMP) actuators (e.g., four) provided on a wristband generate vibrations to provide either local or global haptic sensations. In one embodiment, the EMP actuators are provided on a band intended for a wearable electronic device. Such a band may include (a) a flexible circuit having provided thereon an electrical interface to the wearable electronic device and conductive traces for distributing control signals received from the wearable electronic device over the electrical interface to predetermined locations on the flexible circuit; (b) EMP actuators each being mounted on one of the predetermined locations and each being connected by the conductive traces to receive one or more of the control signals; and (c) a protective covering over the flexible circuit and the EMP actuators. The flexible circuit may be provided, for example, on a kapton substrate, with the conductive traces being provided on the kapton substrate.

In one embodiment, the band of the present invention situates the EMP actuators at regular intervals. Alternatively, the EMP actuators are located such that, when the band is secured around a user's wrist, the EMP actuators are located at 90°, 180°, 270°, and 360° positions relative to the location of the wearable electronic device.

In one embodiment, the conductive traces provide independent individual positive and negative electrodes to each of the EMP actuators. Alternatively, the conductive traces may provide an independent individual positive electrode and a common ground electrode to each of the EMP actuators. The EMP actuators are connected by the conductive traces such that each EMP actuator is capable of being activated independently of the other EMP actuators, being activated in a cyclic fashion, or activated in unison.

In one embodiment, one of the control signals has a frequency in a low vibrational range (e.g., 50-400 Hz, preferably 50-150 Hz) favored for haptic sensations. In addition, one of the the control signals may also have a frequency in the audio range (e.g., up to 24,000 Hz) such that the control signal causes the corresponding actuator to provide an audible sound.

In one embodiment, the protective covering of the band is provided in the form of a silicone rubber strip that is less than 2.0 mm thick, with a hardness that is less than 80 A durometer.

The present invention is better understood upon consideration of the detailed description below in conjunction with the accompanying drawings.

### BRIEF DESCRIPTION OF THE DRAWINGS

FIG. 1(a) shows a top view of silicon wristband 102 in which EMP actuators 101-1, 101-2, 101-3 and 101-4 are embedded, in accordance with one embodiment of the present invention.

FIG. 1(b) shows a side view of silicon wristband.

FIG. 2 shows conductive traces 106, as provided by the laser inscription process.

FIG. 3 shows conductive traces 306 of flexible circuit 303, according to a second embodiment of the present invention.

In these figures, like elements are provided like reference numerals.

### DETAILED DESCRIPTION OF THE PREFERRED EMBODIMENTS

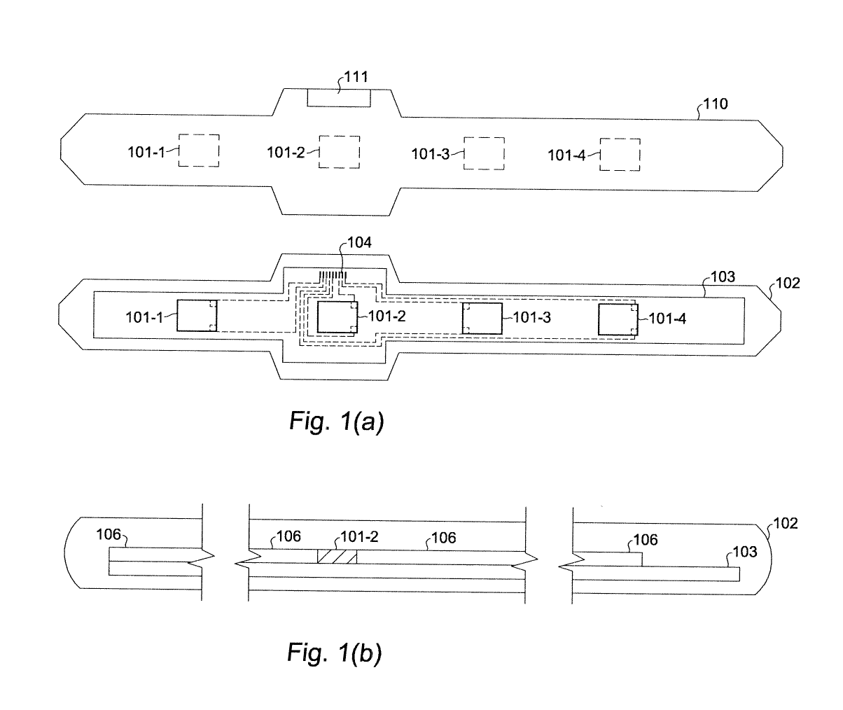

FIG. 1(a) shows a top view of silicon wristband 102 in which EMP actuators 101-1, 101-2, 101-3 and 101-4 are embedded, in accordance with one embodiment of the present invention. FIG. 1 also shows wearable electronic device 110 placed alongside with silicon wristband 102 to show the corresponding locations on wearable device 110 (e.g., a “smart watch”) at which EMP actuators 101-1, 101-2, 101-3 and 101-4 are intended, when wristband 102 is provided on wearable electronic device 110. FIG. 1(b) shows a side view of silicon wristband 102, showing in particular the portion at which EMP actuator 101-2 is embedded. (FIGS. 1(a) and 1(b) are provided to illustrate the exemplary components of wristband 102, and are not drawn to scale).

EMP actuators in this detailed description may be provided, for example, by the ultra-thin EMP transducers described in the U.S. patent application (“Copending Application”), Ser. No. 13/683,963, entitled “Localized Multimodal Electromechanical Polymer Transducers,” filed on Nov. 21, 2012, published as U.S. Patent Application Publication 2014/0035735 A1. The disclosure of the Copending Application is hereby incorporated by reference in its entirety. As described in the Copending Application, each of these EMP transducers may include multiple stacked or laminated ultra-thin EMP actuators, each of thickness 10 microns or less. In one embodiment, the EMP transducers are electrostrictive or relaxor ferroelectric. rather than piezoelectric. Some examples of the EMP transducers include P(VDF-TrFE) modified by either high energy density electron irradiation or by copolymerization with a third monomer. Such EMP actuators respond to an imposed electric field by elongating in a direction perpendicular to the electric field, regardless of the field polarity. Typically, the EMP actuator may generate a more than 1% strain under an electric field of 100 MV/m. With the electrostrictive polymer active layer being less than 10 microns thick, the EMP actuators that may be actuated at a low driving voltage (e.g., 300 volts or less; preferably, 150 volts or less) suitable for use in a wide variety of consumer electronic devices, such as mobile telephones, laptops, ultrabooks, and tablets. When an external electric field is imposed across the EMP layer, the EMP layer becomes charged. The EMP layer thus behaves electrically as a capacitor. (The electric field also provides the electrostrictive response discussed above). The EMP transducers may also serve as sensors that operate at a low charging voltage (e.g., 300 volts or less; preferably, 150 volts or less).

EMP actuators disclosed herein may be actuated by low driving voltages of less than about 300 volts (e.g., less than about 150 volts). These driving voltages typically may generate an electric field of about 40 V/μm or more in the EMP layer of the EMP actuator. The EMP actuators may be driven by a voltage sufficient to generate an electric field that has a DC offset voltage of greater than about 10V, with an alternating component of peak-to-peak voltage of less than 300 volts. (The excitation signal need not be single-frequency; in fact, an excitation signal consisting simultaneously of two or more distinct frequencies may be provided.) The EMP actuators disclosed herein provide a haptic vibration of substantially the same frequency of frequencies as the driving voltage. When the driving voltages are in the audio range (e.g., up to 40,000 Hz, preferably 400-10000 Hz), audible sounds of substantially those in the driving frequency or frequencies may be generated. These EMP actuators are capable of switching between frequencies within about 40 ms, and are thus suitable for use in HD haptics and audio speaker applications. The EMP actuators are flexible and can undergo significant movement to generate high electrostrictive strains. Typically, a surface deformation application would use excitation frequencies in the range between 0-50 Hz, a localized haptic application would use excitation frequencies in the range between 50-400 Hz, preferably 50-150 Hz, and an audio application would use excitation frequencies in the range between 400-24,000 Hz, preferably, 400 to 10,000 Hz, for example.

As shown in FIG. 1(a), wristband 102 may be provided by a flexible silicone strip that is, for example, 2.0 mm thick or less, preferably 1.5 mm or less, with a hardness of less than approximately 80 A durometer, preferably less than 20 A durometer. Embedded in wristband 102 is flexible circuit 103 on which EMP actuators 101-1 to 101-4 are mounted at predetermined locations (e.g., at regular intervals, such as at 90°, 180°, 270° , and 360° positions). In one embodiment, the predetermined locations are approximately 2″ apart so that, once wrapped around the wrist of a typical user, the EMP actuators are positioned on the top side, the right side, the left side, and the bottom side of the user's wrist. Flexible circuit 103 includes connector 104 that couples to an electrical interface 111 provided on wearable electronic device 110. Electrical interface 111 may be provided, for example, at the base of the functional display of the wearable device. Electrical interface 111 provides the control signals that are used to drive each of EMP actuators 101-1 to 101-4.

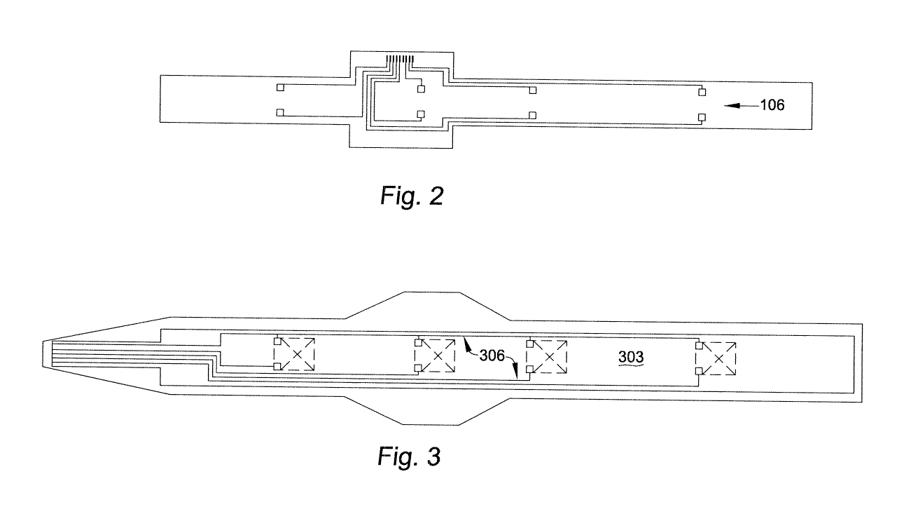

Flexible circuit 103 may be provided by, for example, a 0.001″ thick kapton/copper clad flexible circuit. Other types of flexible circuits known in the art may also be used. Conductive traces 106 on flexible circuit 103 may be provided, for example, using any of many suitable available processes known in the art, including a laser inscription process. Under the laser inscription process, a copper thin film is first cladded onto a substrate (e.g., a kapton substrate). An adhesive tape with a photo-resistive property is then attached to the surface of the copper film. A laser inscribes an image of the intended conductive traces 106 on the surface of the adhesive tape. The energy in the laser activates the photo-resistive property of the adhesive tape, providing a protective layer on the copper film where the conductive traces are intended. The remainder of the adhesive tape (i.e., the portion that is not exposed to the laser) can then be lifted and removed from the copper film, thereby exposing the portion of the copper film that is not covered by the protective layer. The exposed portion of the copper film can then be etched away by a suitable etchant (e.g., a ferric chloride solution). The conductive traces provide the electrodes for controlling the EMP actuators at locations corresponding to the predetermined locations on wristband 102. FIG. 2 shows conductive traces 106, as provided by the laser inscription process. As shown in FIG. 2, in this embodiment, conductive traces 106 provide individual positive and negative electrodes for attaching each of EMP actuators 101-1 to 101-4. After EMP actuators 101-1 to 101-4 are attached (or “populated”) at the corresponding locations on the kapton substrate, flex circuit 103 is then embedded by injection molding in the 1.5 mm thick 20 A silicone rubber that becomes wristband 102.

EMP actuators 101-1 to 101-4 in wristband 102 may provide either local vibrations, including audible vibrations (i.e., sounds), or vibrations that resonate the entire wearable electronic device 110. EMP actuators 101-1 to 101-4 may be actuated to achieve different effects independently, cyclically, in parallel or in any combinations, in-phase or out-of-phase. One advantage of the configuration of EMP actuators 101-1 to 101-4 is the ability of providing either vibration for the entire system or local vibrations by selectively activating one or more of the EMP actuators. In one embodiment, to provide haptic sensations, each of EMP actuators are typically vibrated at an acceleration between 2-7 G. Vibration of the entire system may be much stronger than can be achieved with a linear resonating actuator in the display of wearable electronic device 110, for example. In one embodiment, both low frequency haptic sensation and audible sound are provided by sending to the activated EMP actuators simultaneously or alternately, in rapid succession, control signals having haptic frequencies (i.e., frequencies between 50-400 Hz, preferably frequencies between 50-150 Hz) and audio frequencies (e.g., frequencies up to 24,000 Hz, preferably between 400-10,000 Hz).

Unlike the prior art, by providing the EMP actuators on the wristband, the vibration is not merely provided at one point (i.e., at the functional display or the face plate of the wearable electronic device), but circumferentially at multiple points around the user's wrist. With all of the EMP actuators activated, for example, wristband 102 contributes the mass to be shaken by EMP actuators 101-1 to 101-4, and not merely serves as a dampener, as in the prior art. The present invention thus provides a thin and flexible global haptics experience for any product that uses a wristband (e.g., a smart watch or a fitness or health monitoring device).

FIG. 3 shows conductive traces 306 of flexible circuit 303, according to a second embodiment of the present invention. As shown in FIG. 3, conductive traces 306 provides an individual positive electrode for each EMP actuator to be attached to flexible circuit 303, and a common negative or ground electrode for all of the EMP actuators.

The detailed description above is provided to illustrate the specific embodiments of the present invention and is not intended to be limiting. Numerous modifications and variations within the scope of the present invention are possible. The present invention is set forth in the following claims.

I claim:

1. A band for a wearable electronic device, comprising:
a flexible circuit having provided thereon an electrical interface to the wearable electronic device and conductive traces for distributing control signals received from the wearable electronic device over the electrical interface to predetermined locations on the flexible circuit;
a plurality of electromechanical polymer (EMP) actuators each being mounted on one of the predetermined locations and each being connected by the conductive traces to receive one or more of the control signals; and
a protective covering over the flexible circuit and the EMP actuators.

2. The band of claim 1, wherein the flexible circuit comprises a kapton substrate.

3. The band of claim 2, wherein the conductive traces are formed out of a copper film cladded on the kapton substrate.

4. The band of claim 1, wherein the predetermined locations of the EMP actuators are located at regular intervals.

5. The band of claim 1, wherein the predetermined locations of the EMP actuators are such that, when the band is secured around a user's wrist, the EMP actuators are located at 90°, 180°, 270°, and 360° positions relative to the location of the wearable electronic device.

6. The band of claim 1, wherein the conductive traces provide independent individual positive and negative electrodes to each of the EMP actuators.

7. The band of claim 1, wherein the conductive traces provide an independent individual positive electrode and a common ground electrode to each of the EMP actuators.

8. The band of claim 1, wherein the EMP actuators are connected by the conductive traces such that each EMP actuator is capable of being activated independently of the other EMP actuators.

9. The band of claim 1, wherein the EMP actuators are connected by the conductive traces such that the EMP actuators are capable of being activated in a cyclic fashion.

10. The band of claim 1, wherein the EMP actuators are connected by the conductive traces such that the EMP actuators are capable of being activated in unison.

11. The band of claim 1, wherein one of the control signals has a frequency between 50 Hz and 400 Hz, so as to provide a haptic sensation.

12. The band of claim 11, wherein the frequency is between 50 Hz and 150 Hz.

13. The band of claim 1, wherein one of the control signals has a frequency in the audio range, such that the control signal causes the corresponding actuator to provide an audible sound.

14. The band of claim 1, wherein the protective covering comprises a silicone rubber strip that is less than 2.0 mm thick.

15. The band of claim 1, wherein the protective covering comprises a silicone rubber strip with a hardness that is less than 80 A durometer.
